(19) United States
(12) Patent Application Publication
(10) Pub. No.: US 2025/0391642 A1
(43) Pub. Date: Dec. 25, 2025

(54) IMPEDANCE MATCHING CIRCUIT, PLASMA PROCESS SUPPLY SYSTEM AND PLASMA PROCESS SYSTEM

(71) Applicant: TRUMPF Hüttinger GmbH + Co. KG, Freiburg (DE)

(72) Inventor: Birger Nordmann, Herdecke (DE)

(21) Appl. No.: 19/310,990

(22) Filed: Aug. 27, 2025

Related U.S. Application Data
(63) Continuation of application No. PCT/EP2024/054998, filed on Feb. 27, 2024.

(30) Foreign Application Priority Data
Feb. 28, 2023 (DE) 10 2023 104 942.9

(51) Int. Cl. H01J 37/32

(52) U.S. Cl. CPC H01J 37/32183; H01J 37/32165

(57) ABSTRACT

An impedance matching circuit for a plasma process supply system and a plasma process system, configured for powers≥500 W and frequencies in a range from 2 MHz to 100 MHz, the impedance matching circuit including a matching unit having one or more reactances and a resonator. The impedance matching circuit is configured for operation at a predetermined high frequency (HF) power signal with a predetermined basic frequency and auto-frequency tuning (AFT) bandwidth, limited by a predetermined upper AFT frequency and a predetermined lower AFT frequency. The resonator is configured to not influence the HF power signal at the predetermined basic frequency and to damp the HF power signal and/or influence the HF power signal in a phase at both the predetermined upper and lower AFT frequencies.

### CROSS REFERENCE TO RELATED APPLICATIONS

This application is a continuation of International Application No. PCT/EP2024/054998 (WO 2024/180090 A1), filed on Feb. 27, 2024, and claims benefit to German Patent Application No. DE 10 2023 104 942.9, filed on Feb. 28, 2023. The aforementioned applications are hereby incorporated by reference herein.

### FIELD

The invention relates to an impedance matching circuit, a plasma process supply system and a plasma process system.

### BACKGROUND

Such an impedance matching circuit can be used in systems in which a load is supplied with electrical power, in particular high-frequency power. ‘High frequency’ is also abbreviated to ‘HF’ in the following. HF here refers to frequencies in the range from 2 MHz to 100 MHz, in particular in the range from 10 MHz to 50 MHz.

In such a system, the impedance of the load should be matched to the impedance of the power supply, as otherwise power reflection may occur. The reflection of power has a direct impact on the efficiency of a system; it reduces the effectiveness of a system.

An exemplary system in which an impedance matching circuit can be used may be a plasma process system.

Such a plasma process system can, for example, be a system in which a load, e.g., a plasma process assembly, is supplied with electrical power.

Such a plasma process assembly can, for example, be a plasma process chamber used for industrial plasma processes such as the surface treatment of workpieces, semiconductor manufacturing with plasma or the processing of workpieces with gas lasers.

In such an application, the plasma process assembly serves to generate plasma.

For this purpose, a plasma process assembly may have an electrode which is fed with a high-frequency power signal for generating the plasma, hereinafter referred to as the HF power signal.

Typically, a high-power and in particular high-voltage power supply is required, for which the plasma process assembly can be connected to a high-frequency power supply, hereinafter referred to as HF power supply.

The plasma process taking place in the plasma process assembly has the problem that the electrical load impedance of the plasma process assembly, which occurs during the process, depends on the conditions in the plasma process assembly and can vary greatly. In particular, the properties of the workpiece, electrodes, and gas conditions are taken into account.

For this reason, an impedance matching circuit is usually required to transform the impedance of the load to a nominal impedance of the HF power supply. Such an impedance matching circuit is usually placed between an HF power supply and the plasma process assembly, usually in the immediate vicinity of the plasma process assembly.

An impedance matching circuit is usually an assembly that may have inductors and/or capacitors.

For complex problems where it is important to be able to change the impedance quickly, semiconductor-switched impedance matching circuits are often used. These semiconductor switching elements can be used to switch inductors and/or capacitors in impedance matching circuits on and off. Control circuits can be used to control the switching on and off of the semiconductor switching elements. An example of such a semiconductor-switched impedance matching circuit is disclosed and described in DE 20 2020 102 084 U1.

In principle, such semiconductor-switched impedance matching circuits have only a discrete set of possible output impedances at a given frequency.

By using an AFT-capable (auto-frequency tuning) HF power supply, the set of possible output impedances can be increased because the HF power supply has a frequency band of possible frequencies available to it instead of a single frequency, which is called its bandwidth.

This results in a trajectory of possible output impedances over the frequency for each discrete output impedance. The length of this trajectory is considered a quality characteristic for an impedance matching circuit. The longer the trajectory, the more possible output impedances can be set. However, the bandwidth of the AFT-capable HF power supply still limit the set of possible output impedances.

### SUMMARY

In an embodiment, the present disclosure provides an impedance matching circuit for a plasma process supply system and a plasma process system, configured for powers≥500 W and frequencies in a range from 2 MHz to 100 MHz, the impedance matching circuit comprising a matching unit having one or more reactances and a resonator. The impedance matching circuit is configured for operation at a predetermined high frequency (HF) power signal with a predetermined basic frequency and auto-frequency tuning (AFT) bandwidth, limited by a predetermined upper AFT frequency and a predetermined lower AFT frequency. The resonator is configured to not influence the HF power signal at the predetermined basic frequency and to damp the HF power signal and/or influence the HF power signal in a phase at both the predetermined upper and lower AFT frequencies.

### BRIEF DESCRIPTION OF THE DRAWINGS

Subject matter of the present disclosure will be described in even greater detail below based on the exemplary figures. All features described and/or illustrated herein can be used alone or combined in different combinations. The features and advantages of various embodiments will become apparent by reading the following detailed description with reference to the attached drawings, which illustrate the following:

FIG. 1 illustrates a schematic view of an embodiment of a plasma process system with an impedance matching circuit according to the present disclosure;

FIG. 2a, FIG. 2b, FIG. 2c, and FIG. 2d illustrate various circuit diagrams of resonators;

FIG. 3a illustrates an AFT-capable HF power supply and its output power in a diagram;

FIG. 3b illustrates a resonator as a bandpass filter and its transfer function;

FIG. 4a and FIG. 4b illustrate circuit diagrams of matching units without a semiconductor switching element; and

FIG. 5a, FIG. 5b, FIG. 5c, FIG. 5d, FIG. 5e and FIG. 5f illustrate circuit diagrams of matching units with a semiconductor switching element.

### DETAILED DESCRIPTION

In an embodiment, the present disclosure provides an impedance matching circuit which increases the length of the trajectory of possible output impedances over the frequency and thus increases the set of possible output impedances.

According to the present disclosure, an impedance matching circuit for powers≥500 W and frequencies in the range of 2 MHz to 100 MHz is disclosed, in particular for a plasma process supply system and plasma process system, having:
a) a matching unit having one or a plurality of reactances, e.g., coils and/or capacitors, b) a resonator,
c) wherein the impedance matching circuit is configured for operation at a predetermined HF power signal with a predetermined basic frequency and AFT bandwidth, limited by a predetermined upper AFT frequency and a predetermined lower AFT frequency,
d) wherein the resonator is configured to influence the HF power signal slightly, in particular to not influence same, at the basic frequency and to damp the HF power signal and/or influence it in the phase at least at one of the two AFT frequencies, in particular at both AFT frequencies.

This makes it possible to increase the number of possible output impedances of the impedance matching circuit for frequencies in the range of the bandwidth of the AFT-capable HF power supply and to obtain an impedance matching circuit that improves the length of the trajectory of possible output impedances over the frequency. This also allows the number of components, for example reactances such as coils and/or capacitors, to be kept lower, resulting in a more compact design.

It is particularly advantageous if the resonator is configured to influence the HF power signal slightly, in particular to not influence same, at the basic frequency and to damp the HF power signal and also influence it in the phase at least at one of the two AFT frequencies, in particular at both AFT frequencies.

A “slight influence” means an influence that is very minor within the scope of what is technically reasonably feasible and in any case smaller, in particular by a factor of 10, preferably by a factor of 100, than that at the upper or lower AFT frequency.

The impedance matching circuit can be configured either with fixed reactances or with discrete reactances that can be switched on and off using semiconductors. The output impedance of an impedance matching circuit with fixed reactances can be changed over the frequency. In a semiconductor-switched impedance matching circuit, the output impedance can also be changed by switching reactances on and off. Semiconductor switches such as PIN diodes or metal-oxide-semiconductor field-effect transistors (MOSFETs) can be used for this switching on and off, which can be controlled via a drive circuit.

Impedance matching circuits with fixed reactances offer the advantage of being simple and inexpensive to design and do not require expensive components such as semiconductor switching elements. Semiconductor-switched impedance matching circuits offer significantly more variability in their output impedance and can also change the output impedance very quickly. Both together lead to a significantly wider range of possible applications for semiconductor-switched impedance matching circuits.

The resonator of the impedance matching circuit can be configured as a bandpass filter. This makes it particularly easy to construct the resonator with minimal components.

The resonator of the impedance matching circuit can have a series and/or parallel resonator. This means that the structure of the impedance matching circuit is variable and can be adapted to different conditions. For the precise implementation of the resonator, one or a plurality of discrete capacitors and/or one or a plurality of discrete inductors can be used. The capacitors and/or inductors can be replaced individually or in combination by line arrangements. A resonator can, for example, be realized by a 24 line that is open at the end or terminated with a short circuit. A is the wavelength corresponding to the resonant frequency.

In an aspect, the resonator is connected downstream of the matching unit. This can improve the properties of the trajectory.

In an aspect, the resonator and the matching unit are constructed independently of each other. This means that the resonator and matching unit do not have any common components. In this way, the properties of the resonator can be adjusted particularly well.

For implementation with discrete reactances, for example, a planar inductor on a circuit board and/or a vacuum or ceramic capacitor and/or a capacitor formed by rejected conductive surfaces on a circuit board can be used. The components can be connected in series or parallel. If the resonator is implemented by a line arrangement, the additional feeding of a second frequency at the end of the impedance matching circuit can be provided for. Even when implemented using a line arrangement, a resonator can be provided that effectively acts either as a parallel or as a series resonator.

Furthermore, the impedance matching circuit can be used in a plasma process supply system or a plasma process system.

Such a plasma process supply system can include, in addition to the impedance matching circuit, an AFT-capable HF power supply for providing the HF power signal. The impedance matching circuit can be electrically connected to the AFT-capable HF power supply and can also be configured to be connected to a plasma process assembly.

In a plasma process system, such a plasma process assembly can be present and connected to the plasma process supply system. The plasma process assembly can be supplied with power from the HF power signal via the plasma process supply system.

Embodiments of the present disclosure are shown schematically in the drawings and are explained in more detail below with reference to the figures.

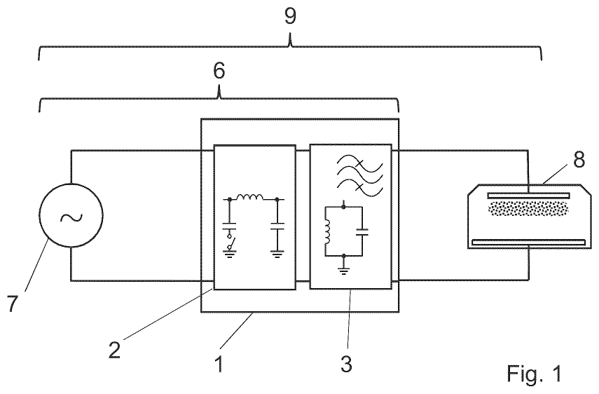

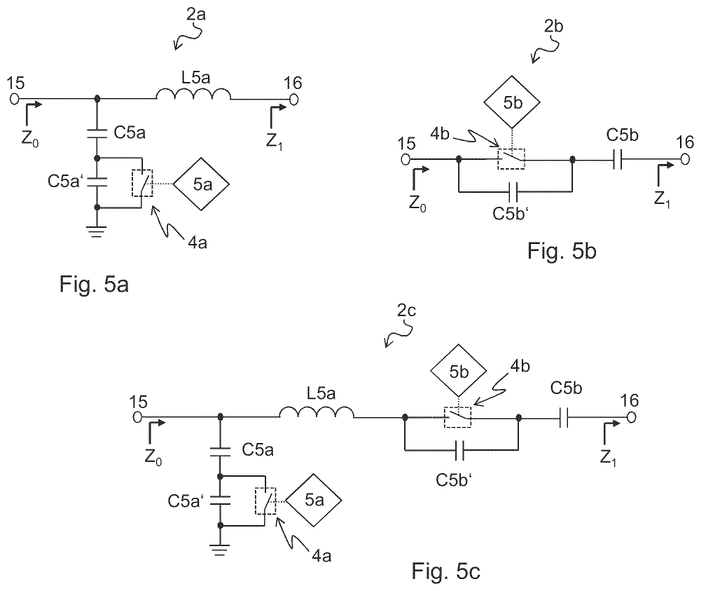

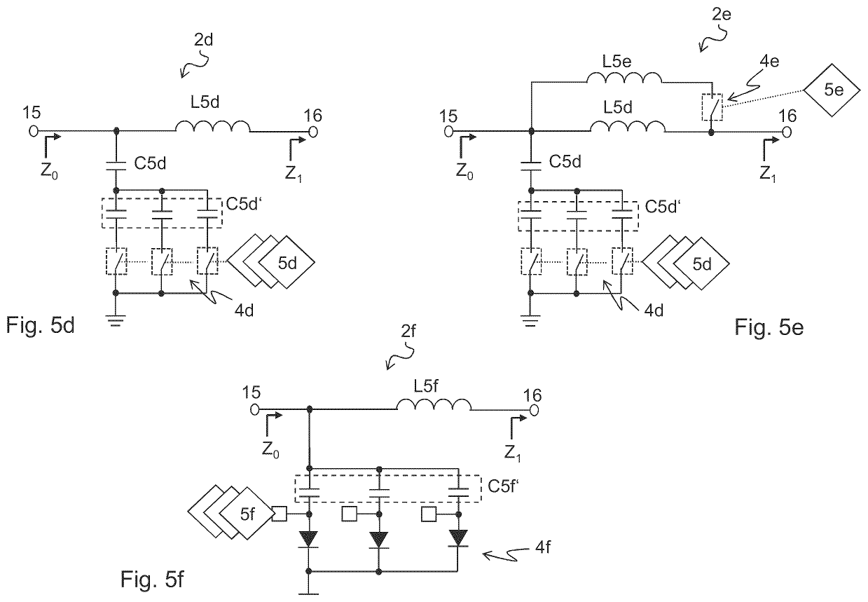

FIG. 1 shows an embodiment of an exemplary plasma process system 9. The plasma process system 9 has a plasma process supply system 6 and a plasma process assembly 8. The plasma process supply system 6 comprises an impedance matching circuit 1 according to the present disclosure and an AFT-capable HF power supply 7. The impedance matching circuit 1 has a matching unit 2 and a resonator 3. The matching unit 2 has one or a plurality of reactances, for example. The reactances can be coils and/or capacitors. Examples of such matching units 2 are shown in FIGS. 4a to 4b. In addition, the impedance matching circuit 1 can have semiconductor switching elements 4 and a drive circuit 5 that can switch reactances on and off to change the output impedance. Examples of such matching units 2 are shown in FIGS. 5a to 5f.

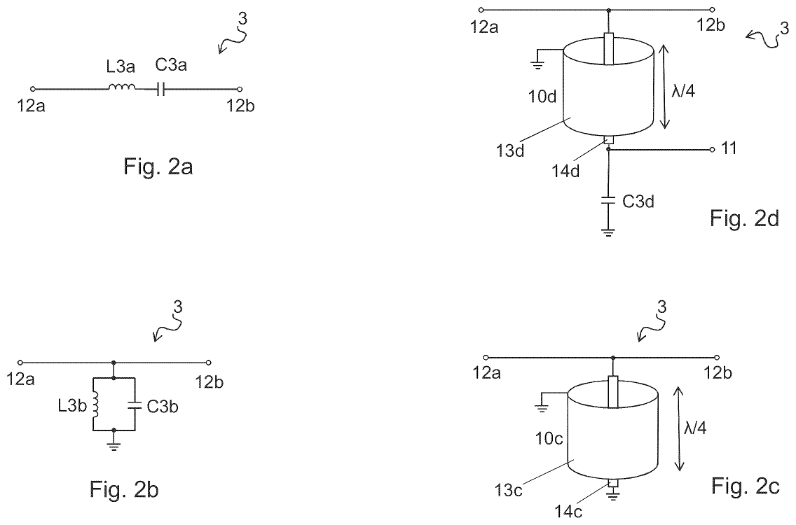

The resonator 3 can be implemented in different ways. FIGS. 2a to 2d show a plurality of possibilities for the resonator 3.

FIGS. 2a to 2d show a selection of possibilities for the resonator 3 of the impedance matching circuit 1 according to the present disclosure. The resonators 3 each have two connection options 12a, 12b, via which a resonator 3 can be integrated into the impedance matching circuit 1.

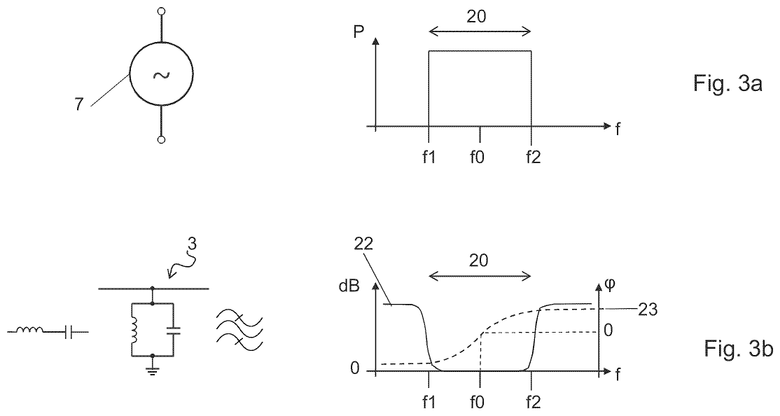

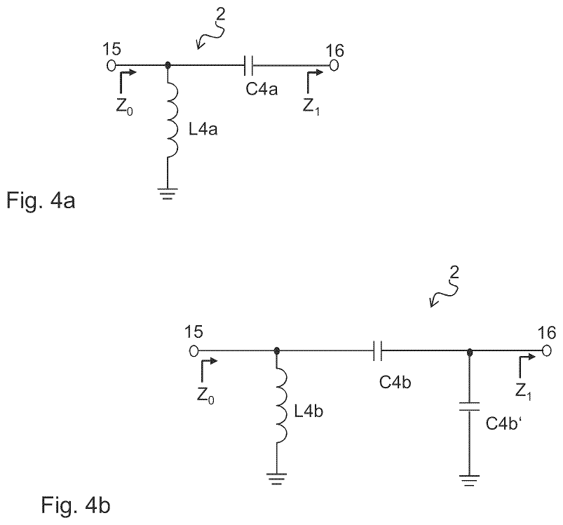

In FIG. 2a, a series resonator is shown as resonator 3, which has an inductor L3a and a capacitor C3a connected in series. This series resonator is connected between the two connection options 12a, 12b. With appropriate design of the inductor L3a and the capacitor C3a, it can have a transfer function as shown in FIG. 3b.

FIG. 2b shows a parallel resonator having an inductor L3b and a capacitor C3b connected in parallel. This parallel resonator is connected between the two connection options 12a, 12b and ground. With appropriate design of the inductor L3b and the capacitor C3b, it can have a transfer function as shown in FIG. 3b.

FIG. 2c shows a parallel resonator realized by a line arrangement 10c. The line arrangement 10c can have a coaxial or microstrip line. It can be adjusted to the characteristic impedance at this point, e.g., 50Ω. Their length can preferably be λ/4, where λ is the wavelength of the basic frequency f0 (shown in FIG. 3). The line arrangement 10c has an outer conductor 13c which is connected to ground. The line arrangement 10c has a signal conductor 14c, which is also connected to ground at its end and to the two connection options 12a, 12b at the other end. This creates a parallel resonant circuit which does not influence the signal flowing between the two connection options 12a, 12b at the basic frequency f0, but causes attenuation and/or phase shift at adjacent frequencies.

FIG. 2d shows the same parallel resonator as FIG. 2c, except that here a second additional frequency can be fed in via a second frequency feed 11. For this purpose, the resonator 3 has an, in particular discrete, capacitor C3d, which is connected in series to the line arrangement 10d and is dimensioned large enough that the resonator 3 acts like a short circuit for the basic frequency f0. If this effect is not sufficient as a short circuit, this can be compensated by adjusting the length of the line arrangement 10d. This means that this resonator 3 cannot influence the signal flowing between the two connection options 12a, 12b at the basic frequency f0, but can cause attenuation and/or phase shift at adjacent frequencies. The line arrangement 10d has an outer conductor 13d and a signal conductor 14d.

It is also provided to realize the series resonant circuit from FIG. 2a with a λ/4 line.

In FIG. 3a, an AFT-capable HF power supply 7 and its output power P are shown in a diagram representing the power versus frequency f. The possible output power of the AFT-capable HF power supply 7 is constant over the entire AFT bandwidth 20. This means that the HF power supply 7 can deliver an output signal with a power spanned within the rectangle of f1, f2 from the lower AFT frequency f1 to the upper AFT frequency f2.

FIG. 3b shows two embodiments of the resonator 3 from FIGS. 2a, 2b. Since this acts as a bandpass filter, a transfer function can be represented for it. The function 22 shows the attenuation curve in dB. At the basic frequency f0 the damping is close to or equal to zero, so there is comparatively little or no damping. The damping increases at the lower AFT frequency f1 and at the upper AFT frequency f2. At the same time, the phase is influenced, which is shown in the dashed line 23. At the basic frequency f0, the phase influence is zero or close to zero. The phase shift increases towards the upper AFT frequency f2. The phase shift decreases towards the lower AFT frequency f1. Accordingly, the resonator 3 is configured to influence the HF power signal slightly, in particular to not influence same, at the basic frequency f0 and to damp the HF power signal and/or influence it in the phase at least at one of the two AFT frequencies f1, f2, in particular at both AFT frequencies f1, f2. The range between the two AFT frequencies f1, f2 represents the AFT bandwidth 20.

In FIG. 4a and FIG. 4b, two different circuit diagrams of matching units 2 are shown, which do not have a semiconductor switching element 4 in these exemplary embodiments.

FIG. 4a shows a typical L-shaped matching unit 2 having an inductor L4a and a capacitor C4a. The inductor L4a is connected from the input 15 to ground. The capacitor C4a is connected between input the 15 and the output 16. This matching unit 2 is configured to convert the impedance Z1 into the impedance Z0.

In FIG. 4b a typical matching unit is shown in x-shape, which has an inductor L4b and two capacitors C4b, C4b′. The inductor L4b is connected from the input 15 to ground. The capacitor C4b is connected between the input 15 and the output 16. The capacitor C4b′ is connected from the output 16 to ground.

This matching unit 2 is configured to convert the impedance Z1 into the impedance Z0.

FIGS. 5a to f show various circuit diagrams of matching units 2a-2f, which in these embodiments are configured with one or a plurality of semiconductor switching elements 4a-4f and one or a plurality of drive circuits 5a-5f.

FIG. 5a shows a typical L-shaped matching unit having an inductor L5a and two capacitors C5a, C5a′. The inductor L5a is connected between the input 15 and the output 16. The capacitors C5a, C5a′ are connected in series and this series connection is connected from the input 15 to ground. The capacitor C5a′ is connected directly to ground. A semiconductor switching element 4a is connected in parallel to the capacitor C5a′. This semiconductor switching element 4a is connected to a drive circuit 5a which is configured to switch the semiconductor switching element 4a on and off. When the semiconductor switching element 4a is turned on, the capacitor C5a′ is short-circuited and the resulting capacitance value of the series circuit is equal to the capacitance value of the capacitor C5a. When the semiconductor switching element 4a is turned off, the capacitor C5a′ is not short-circuited and the resulting capacitance value of the series circuit is equal to that of a series circuit of the two capacitors C5a, C5a′.

This matching unit 2a is configured to convert the impedance Z1 into the impedance Z0 and can be changed by the drive circuit 5a.

FIG. 5b shows a typical matching unit 2b having two capacitors C5b, C5b′. The capacitor C5b is connected in series with a semiconductor switching element 4b. This series circuit consisting of the capacitor C5b and the semiconductor switching element 4b is connected between the input 15 and the output 16. The capacitor C5b′ is connected in parallel to the semiconductor switching element 4b. The semiconductor switching element 4b is connected to a drive circuit 5b which is configured to switch the semiconductor switching element 4b on and off. When the semiconductor switching element 4b is turned on, the capacitor C5b′ is short-circuited and the resulting capacitance value of the matching unit 2b is equal to that of the capacitor C5b. When the semiconductor switching element 4b is turned off, the capacitor C5b′ is not short-circuited and the resulting capacitance value of the matching unit 2b is equal to that of a series connection of the two capacitors C5b, C5b′.

This matching unit 2b is configured to convert the impedance Z1 into the impedance Z0 and can be changed by the drive circuit 5b.

FIG. 5c shows a typical matching unit 2c which has a series connection of the two matching units 2a, 2b from FIG. 5a and FIG. 5b. This series circuit is connected between the input 15 and the output 16. The function of the matching unit 2c, i.e., the series connection of the matching units 2a, 2b, results from the functions of the individual matching units 2a, 2b described in the descriptions of FIG. 5a and FIG. 5b, only combined as a series connection.

This matching unit 2c is configured to convert the impedance Z1 into the impedance Z0 and can be changed by the drive circuit 5a, 5b.

FIG. 5d shows a typical L-shaped matching unit 2d having an inductor L5d, a capacitor C5d, three further capacitors C5d′, and three semiconductor switching elements 4d. The inductor L5d is connected between the input 15 and the output 16. The capacitor C5d is connected in series with a parallel circuit consisting of the three other capacitors C5d′ and the three semiconductor switching elements 4d. This parallel circuit has three parallel series circuits consisting of a capacitor C5d′ and a semiconductor switching element 4d. Each semiconductor switching element 4d is connected to a drive circuit 5d which is configured to switch the semiconductor switching elements 4d on and off. When one of the three semiconductor switching elements 4d is switched on, the capacitor C5d is connected in series with one of the three capacitors C5d′. This series circuit is connected from the input 15 to ground. If one or both of the further semiconductor switching elements 4d are also switched on, the capacitor C5d is connected in series with a parallel circuit of two or three of the capacitors C5d′. This parallel circuit can be extended by further parallel series circuits, but it can also have only two parallel series circuits. When all semiconductor switching elements 4d are turned off, the capacitors C5d, C5d′ have no influence on the impedance of the matching unit 2d. In this case, the impedance results solely from the inductor L5d.

This matching unit 2d is configured to convert the impedance Z1 into the impedance Z0 and can be changed by the drive circuit 5d.

FIG. 5e shows a typical L-shaped matching unit 2e having the matching unit 2d of FIG. 5d. In addition to the matching unit 2d described in the description of FIG. 5d, here this matching unit 2e has an additional inductor Le and an additional semiconductor switching element 4c. The inductor L5e is connected in series with the semiconductor switching element 4c. The series circuit is connected in parallel to the inductor L5d. The semiconductor switching element 4e is connected to a drive circuit 5e which is configured to switch the semiconductor switching element 4e on and off. When the semiconductor switching element 4c is switched on, the two inductors L5c, L5d are connected in parallel. When the semiconductor switching element 4c is turned off, the inductor L5c has no influence on the impedance of the matching unit 2e and the matching unit 2e corresponds to the matching unit 2d of FIG. 5d.

This matching unit 2e is configured to convert the impedance Z1 into the impedance Z0 and can be changed by the drive circuits 5d, 5c.

FIG. 5f shows a typical L-shaped matching unit 2f having an inductor L5f as well as three further capacitors C5f and three semiconductor switching elements 4f. The three semiconductor switching elements 4f are configured as PIN diodes. The inductor L5f is connected between the input 15 and the output 16. The semiconductor switching elements 4f are each connected in series with a capacitor C5f. These three series circuits are connected in parallel. This parallel circuit can be extended by further parallel series circuits, but it can also have only two parallel series circuits. Each semiconductor switching element 4f is connected to a drive circuit 5f which is configured to switch the semiconductor switching elements 4f on and off. When one of the three semiconductor switching elements 4f is switched on, one of the three capacitors C5f is connected from the input 15 to ground. If one or the other two semiconductor switching elements 4f are also switched on, a parallel circuit of two or three capacitors C5f is connected from the input to ground. When all semiconductor switching elements 4f are turned off, the capacitors C5f have no influence on the impedance of the matching unit 2f. In this case, the impedance results solely from the inductor L5f.

This matching unit 2f is configured to convert the impedance Z1 into the impedance Z0 and can be changed by the drive circuits 5f.

The previously described matching units 2, 2a-2f can be varied, so that instead of capacitors, depending on the desired matching, inductors can be used, or instead of inductors, depending on the desired matching, capacitors can be used.

The previously described matching units 2, 2a-2f can be used individually or in combination of two or more.

With the features described above, the number of components, such as semiconductor switching elements or reactances, e.g., coils and/or capacitors as well as capacitors and/or inductors, can be kept lower, thus achieving a more compact design.

While subject matter of the present disclosure has been illustrated and described in detail in the drawings and foregoing description, such illustration and description are to be considered illustrative or exemplary and not restrictive. Any statement made herein characterizing the invention is also to be considered illustrative or exemplary and not restrictive as the invention is defined by the claims. It will be understood that changes and modifications may be made, by those of ordinary skill in the art, within the scope of the following claims, which may include any combination of features from different embodiments described above.

The terms used in the claims should be construed to have the broadest reasonable interpretation consistent with the foregoing description. For example, the use of the article “a” or “the” in introducing an element should not be interpreted as being exclusive of a plurality of elements. Likewise, the recitation of “or” should be interpreted as being inclusive, such that the recitation of “A or B” is not exclusive of “A and B,” unless it is clear from the context or the foregoing description that only one of A and B is intended. Further, the recitation of “at least one of A, B and C” should be interpreted as one or more of a group of elements consisting of A, B and C, and should not be interpreted as requiring at least one of each of the listed elements A, B and C, regardless of whether A, B and C are related as categories or otherwise. Moreover, the recitation of “A, B and/or C” or “at least one of A, B or C” should be interpreted as including any singular entity from the listed elements, e.g., A, any subset from the listed elements, e.g., A and B, or the entire list of elements A, B and C.

1. An impedance matching circuit for a plasma process supply system and a plasma process system, configured for powers≥500 W and frequencies in a range from 2 MHz to 100 MHz, the impedance matching circuit comprising:
a) a matching unit having one or more reactances; and
b) a resonator,
c) wherein the impedance matching circuit is configured for operation at a predetermined high frequency (HF) power signal with a predetermined basic frequency and auto-frequency tuning (AFT) bandwidth, limited by a predetermined upper AFT frequency and a predetermined lower AFT frequency, and
d) wherein the resonator is configured to not influence the HF power signal at the predetermined basic frequency and to damp the HF power signal and/or influence the HF power signal in a phase at both the predetermined upper and lower AFT frequencies.

2. The impedance matching circuit according to claim 1, wherein the impedance matching circuit is implemented as an impedance matching circuit with fixed reactances.

3. The impedance matching circuit according to claim 1, wherein the impedance matching circuit is implemented as a semiconductor-switched impedance matching circuit and has, for this purpose, semiconductor switching elements and a drive circuit which are configured to switch reactances on and off.

4. The impedance matching circuit according to claim 1, wherein the resonator is configured as a bandpass filter.

5. The impedance matching circuit according to claim 1, wherein the resonator has a series resonator.

6. The impedance matching circuit according to claim 1, wherein the resonator has a parallel resonator.

7. The impedance matching circuit according to claim 1, wherein the resonator has a discrete capacitor and a discrete inductor.

8. The impedance matching circuit according to claim 1, wherein the resonator is realized by a line arrangement that acts like a parallel or series resonator.

9. The impedance matching circuit according to claim 1, wherein the resonator is connected downstream of the matching unit.

10. The impedance matching circuit according to claim 1, wherein the resonator and the matching unit are constructed independently of one another.

11. The impedance matching circuit according to claim 1, wherein the resonator is configured to not influence the HF power signal at the basic frequency and to damp the HF power signal and influence it in the phase at both AFT frequencies.

12. A plasma process supply system comprising:
an AFT-capable HF power supply for providing the HF power signal; and
the impedance matching circuit according to claim 1, wherein the impedance matching circuit is electrically connected to the AFT-capable HF power supply and is configured to be connected to a plasma process assembly.

13. A plasma process system having the plasma process supply system according to claim 12 and a plasma process assembly, wherein the plasma process assembly is connected to the plasma process supply system and the plasma process supply system is configured to supply the plasma process assembly with power from the HF power signal.
